(19) United States
(12) Patent Application Publication
(10) Pub. No.: US 2025/0311182 A1
(43) Pub. Date: Oct. 2, 2025

(54) TRAY ALIGNMENT DEVICE AND TRAY ALIGNMENT INSPECTION METHOD USING THE SAME

(71) Applicant: Samsung Display Co., Ltd., Yongin-Si (KR)

(72) Inventor: Woong Il CHOI, Yongin-si (KR)

(21) Appl. No.: 18/898,671

(22) Filed: Sep. 27, 2024

(30) Foreign Application Priority Data
Apr. 1, 2024 (KR) 10-2024-0044202

(51) Int. Cl. H05K 13/02; H05K 13/08

(52) U.S. Cl. CPC H05K 13/022; H05K 13/021; H05K 13/0813

(57) ABSTRACT

An embodiment of a tray alignment device includes a stage, a supply module, an alignment module, and an inspection module. The supply module supplies a tray to the stage. The alignment module is disposed to surround the tray supplied to the stage and align the tray by pressing at least a portion of an edge of the tray. The inspection module inspects an alignment of the tray.

### CROSS-REFERENCE TO RELATED APPLICATION

This application claims priority from Korean Patent Application No. 10-2024-0044202 filed on Apr. 1, 2024, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a tray alignment device and a tray alignment inspection method using the same.

### 2. Description of the Related Art

The importance of display devices is increasing with the development of multimedia. Accordingly, various types of display devices such as an organic light emitting display (OLED) and a liquid crystal display (LCD) are being used. The application examples of such display devices are diversifying, focusing on various mobile electronic devices, for example, portable electronic devices such as smartphones, smart watches, and tablet PCs.

The display device may be transported and stored on a tray while going through various manufacturing processes. The tray includes a seating portion for loading a display device to be loaded. The tray is aligned by a tray alignment device, and the display device is seated on the seating portion of the aligned tray and loaded thereon. When the tray is not aligned in a correct position during a process of loading the display device on the tray, the display device may not be seated on the seating portion of the tray.

### SUMMARY

Embodiments of the present disclosure provide a tray alignment device that may inspect whether a tray aligned by the tray alignment device is aligned in a correct position and a tray alignment inspection method using the same.

However, embodiments of the present disclosure are not limited to that set forth above. The above and other embodiments of the present disclosure will become more apparent to one of ordinary skill in the art to which the present disclosure pertains by referencing the detailed description of the present disclosure given below.

According to one or more embodiments of the present disclosure, a tray alignment device includes a stage, a supply module that supplies a tray to the stage, an alignment module disposed to surround the tray supplied to the stage and aligning the tray by pressing at least a portion of an edge of the tray, and an inspection module that inspects an alignment of the tray.

The supply module may include an adsorption portion disposed above the stage and including an adsorption nozzle for adsorbing the tray, a first moving portion that moves the adsorption portion in a first direction, and a second moving portion that moves the adsorption portion in a second direction.

The first direction may be a direction perpendicular to an upper surface of the stage, and the second direction may be a direction parallel to the upper surface of the stage.

A plurality of trays are provided and arranged to be spaced apart from each other on the upper surface of the stage, and the second direction may be a direction parallel to a direction in which the trays are arranged.

The inspection module may be disposed on the adsorption portion to be positioned above the tray.

The alignment module may include an alignment member disposed adjacent to at least the portion of the edge of the tray, and an actuator that pushes the alignment member toward the tray so that the alignment member contacts and presses at least a portion of the edge of the tray.

The tray includes a first alignment surface extending in one direction and a second alignment surface extending in an obtuse direction relative to the one direction, and the alignment member includes a first pressing surface extending in the one direction to press the first alignment surface and a second pressing surface extending in the obtuse direction to press the second alignment surface.

An extension length of the first pressing surface of the alignment member may be smaller than an extension length of the first alignment surface of the tray, so that an entirety of the first pressing surface may be in contact with the first alignment surface, and an extension length of the second pressing surface of the alignment member may be equal to or longer than an extension length of the second alignment surface of the tray, so that the second pressing surface may be in contact with an entirety of the second alignment surface.

The inspection module may include a transfer rail disposed on the adsorption portion, a transfer block disposed on the transfer rail and transferred along the transfer rail, a camera holder disposed on the transfer block, and a camera disposed in or on the camera holder and to photograph a contact area where the tray and the alignment member come into contact.

The transfer rail may extend in a direction horizontally perpendicular to the second direction.

The inspection module may further include a display unit that displays an image photographed by the camera, and a control unit that determines the alignment state of the tray by analyzing the image displayed on the display unit.

According to one or more embodiments of the present disclosure, tray alignment inspection method includes a tray supply step of supplying a tray to a stage, a tray alignment step of aligning the tray supplied to the stage, and a tray alignment inspection step of inspecting an alignment state of the tray aligned on the stage.

The tray supply step may include a first supply step in which an adsorption portion moves in a second direction so that the adsorption portion for adsorbing the tray is positioned above the tray positioned outside the stage, a second supply step in which the adsorption portion moves in a first direction so as to be in contact with the tray, a third supply step in which the tray is adsorbed to the adsorption portion, a fourth supply step in which the adsorption portion that adsorbs the tray moves in the first direction, a fifth supply step in which the adsorption portion moves in the second direction so as to be positioned above the stage, a sixth supply step in which the adsorption portion moves in the first direction so that the tray is seated on an upper surface of the stage, and a seventh supply step in which the adsorption of the adsorption portion and the tray is released.

The first direction may be a direction perpendicular to the upper surface of the stage, and the second direction may be a direction parallel to the upper surface of the stage.

In the sixth supply step, the tray may be seated on the upper surface of the stage so that at least a portion of an edge of the tray is disposed adjacent to an alignment member disposed on the upper surface of the stage.

In the tray alignment step, the alignment member may contact and press at least a portion of the edge of the tray.

The tray alignment step, a first pressing surface of the alignment member may contact a first alignment surface of the tray and press the first alignment surface, and a second pressing surface of the alignment member may contact a second alignment surface of the tray and presses the second alignment surface.

The tray alignment inspection step may include a first inspection step in which the adsorption portion moves in the second direction so that a camera disposed on the adsorption portion is positioned above the tray, a second inspection step in which the camera moves to be positioned above at least one of a contact area where the first pressing surface contacts the first alignment surface and a contact area where the second pressing surface contacts the second alignment surface, and a third inspection step in which the camera photographs at least one of the contact areas.

The tray alignment inspection step may further include a fourth inspection step in which an image photographed by the camera is displayed on a display unit, and a fifth inspection step of determining the alignment state of the tray by analyzing the image displayed on the display unit.

The fifth inspection step may include a fifth_first inspection step of setting a virtual reference line above the stage, a fifth_second inspection step of determining whether an entirety of the first alignment surface is positioned on the reference line, a fifth_third inspection step of determining whether the second pressing surface and an entirety of the second alignment surface are in contact with each other, and a fifth_fourth inspection step of determining the alignment state of the tray according to the determination results of the fifth_second inspection step and the fifth_third inspection step.

In the fifth_fourth inspection step, when it is determined in the fifth_second inspection step that the entirety of the first alignment surface is positioned on the reference line and it is determined in the fifth_third inspection step that the second pressing surface and the entirety of the second alignment surface are in contact with each other, it is determined that the tray is positioned in a correct position.

The fifth inspection step may include a fifth_first inspection step of determining whether an entirety of the first pressing surface and the first alignment surface are in contact with each other, a fifth_second inspection step of determining whether the second pressing surface and an entirety of the second alignment surface are in contact with each other, and a fifth_third inspection step of determining the alignment state of the tray according to the determination results of the fifth_first inspection step and the fifth_second inspection step.

In the fifth_third inspection step, when it is determined in the fifth_first inspection step that the entirety of the first pressing surface and the first alignment surface are in contact with each other and it is determined in the fifth_second inspection step that the second pressing surface and the entirety of the second alignment surface are in contact with each other, it is determined that the tray is positioned in a correct position.

According to the tray alignment device and the tray alignment inspection method according to the present disclosure, it may be inspected whether the tray is aligned in the correct position.

Further, according to the tray alignment device and the tray alignment inspection method according to the present disclosure, by determining whether the tray is aligned in the correct position before loading the display device on the tray, and not loading the display device on the tray when the tray is not aligned in the correct position, damage to the display device due to tray misalignment may be prevented.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a front view illustrating a tray alignment device according to an example embodiment of the present disclosure;

FIG. 2 is a side view of FIG. 1;

FIG. 3 is a plan view illustrating a tray aligned by the tray alignment device of FIG. 1;

FIG. 4 is a plan view illustrating a stage and an alignment module of FIG. 1;

FIG. 5 is a front view illustrating an inspection module of FIG. 1;

FIG. 6 is a side view of FIG. 5;

FIG. 7 is a flow chart illustrating a tray alignment inspection method according to an example embodiment of the present disclosure;

FIG. 8 is a flowchart illustrating a tray supply step of FIG. 7;

FIG. 9 is a view illustrating a first supply step of FIG. 8;

FIG. 10 is a view illustrating a second supply step of FIG. 8;

FIG. 11 is a view illustrating a fourth supply step of FIG. 8;

FIG. 12 is a view illustrating a fifth supply step of FIG. 8;

FIG. 13 is a view illustrating a sixth supply step of FIG. 8;

FIG. 14 is a view illustrating a seventh supply step of FIG. 8;

FIGS. 15 and 16 are views illustrating a tray alignment step of FIG. 7;

FIG. 17 is a flowchart illustrating a tray alignment inspection step of FIG. 7;

FIG. 18 is a view illustrating a first inspection step of FIG. 17;

FIG. 19 is a view illustrating a second inspection step of FIG. 17;

FIG. 20 is a flowchart illustrating a fifth inspection step of FIG. 17;

FIG. 21 is a view illustrating a fifth inspection step of FIG. 20;

FIG. 22 is a flowchart illustrating another example of the fifth inspection step of FIG. 17; and

FIG. 23 is a view illustrating a fifth inspection step of FIG. 22.

### DETAILED DESCRIPTION OF THE EMBODIMENTS

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

Hereinafter, specific example embodiments will be described with reference to the accompanying drawings.

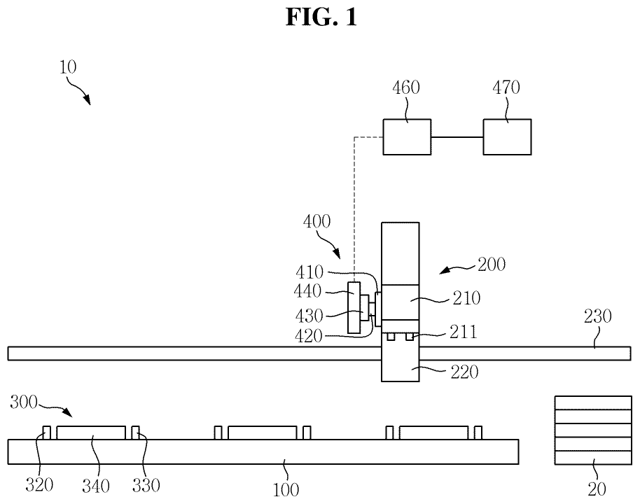

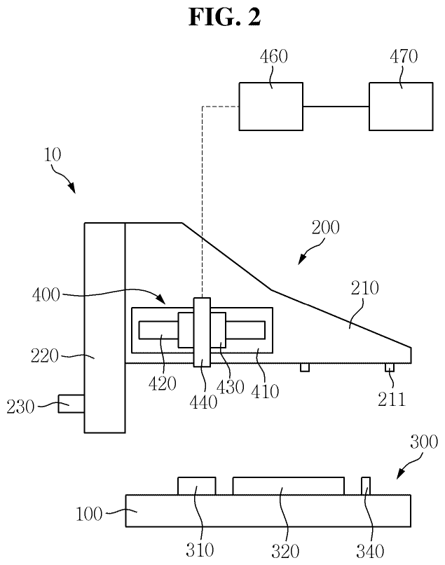

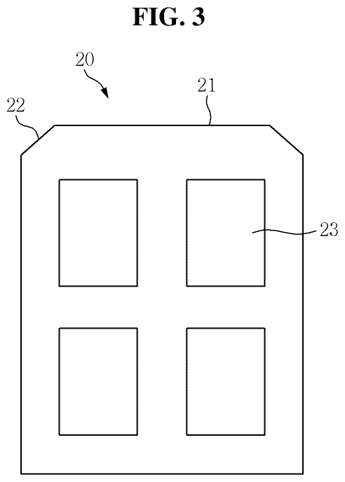

FIG. 1 is a front view illustrating a tray alignment device 10 according to an example embodiment of the present disclosure. FIG. 2 is a side view of FIG. 1. FIG. 3 is a plan view illustrating a tray aligned by the tray alignment device 10 of FIG. 1.

Referring to FIGS. 1 to 3, the tray alignment device 10 may align trays 20 for loading a display device and inspect whether trays 20 are aligned in a correct position. The tray alignment device 10 may include a stage 100, a supply module 200, an alignment module 300, and an inspection module 400.

The stage 100 may provide a space for the trays 20 to be aligned. The stage 100 may support one or more of the supply module 200, the alignment module 300, and the inspection module 400. When the stage 100 supports the supply module 200, a separate support member (not illustrated) may be connected to the stage 100 and the supply module 200, so that the supply module 200 may be supported by the support member and the stage 100. The alignment module 300 is disposed to be seated on an upper surface of the stage 100 so that the alignment module 300 may be supported by the stage 100.

A tray 20 may be seated on the upper surface of the stage 100. The tray 20 may be supplied to the upper surface of the stage 100 by the supply module 200 and seated on the upper surface of the stage 100 so as to be disposed near the alignment module 300. A seating portion 23 for loading a display device may be formed in the tray 20. For example, the seating portion 23 may be provided as a slot that is recessed inward from the upper surface of the tray 20, and as the display device is seated on the seating portion 23, the tray 20 may load the display device. In addition, a first alignment surface 21 extending in one direction and a second alignment surface 22 extending in a direction that is different from the one direction may be formed on an edge of the tray 20. For example, when the tray 20 is formed in a shape of a square box, the first alignment surface 21 may be one side of the tray 20, and second alignment surfaces 22 may be sides that extends obliquely from ends of the first alignment surface 21 toward surfaces of the tray 20 that are perpendicular to the alignment surface 21. The directions that extend obliquely may be referred to as first and second oblique directions. A plurality of trays 20 may be provided and supplied to the upper surface of the stage 100 by the supply module 200. The trays 20 supplied to the upper surface of the stage 100 may be arranged to be spaced apart from each other on the upper surface of the stage 100.

The supply module 200 may supply the tray 20 to the stage 100. The supply module 200 may include an adsorption portion 210, a first moving portion 220, and a second moving portion 230.

The adsorption portion 210 may be disposed above the stage 100 and may include an adsorption nozzle 211 for adsorbing the tray 20. A plurality of adsorption nozzles 211 may be provided and arranged to be spaced apart from each other on a lower surface of the adsorption portion 210. The adsorption portion 210 may adsorb the tray 20 loaded on the outside of the stage 100 and supply the tray to the stage 100. The adsorption portion 210 may be connected to the first moving portion 220 and the second moving portion 230 and may be moved by the first moving portion 220 and the second moving portion 230.

The first moving portion 220 may move the adsorption portion 210 in a first direction. The first moving portion 220 may be disposed to be connected to one side of the adsorption portion 210. For example, the first moving portion 220 may be provided as an actuator, such as a cylinder, and move the adsorption portion 210 in the first direction by operating the actuator. The first direction may be a direction perpendicular to the upper surface of the stage 100. In other words, the first direction may be an up and down direction of FIG. 1.

The second moving portion 230 may move the adsorption portion 210 in a second direction. The second moving portion 230 may be disposed to be connected to one side of the first moving portion 220. The second moving portion 230 may be disposed above the stage 100 to provide a path along which the first moving portion 220 moves. The second moving portion 230 may be connected to the stage 100 by a support member and supported by the support member and the stage 100. The second moving portion 230 may be provided as a rail extending in the second direction, and as the first moving portion 220 moves along the second moving portion 230, the adsorption portion 210 may be moved in the second direction. The second direction may be a direction parallel to the upper surface of the stage 100. In other words, the second direction may be a left and right direction of FIG. 1. In addition, the second direction may be a direction in which the plurality of trays 20 are arranged on the upper surface of the stage 100.

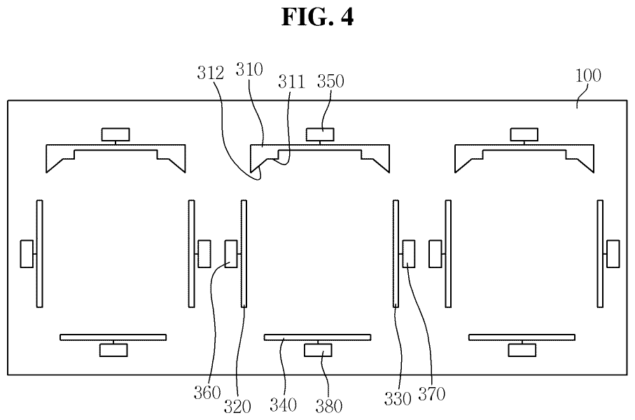

FIG. 4 is a plan view illustrating a stage 100 and an alignment module 300 of FIG. 1.

Referring to FIGS. 3 and 4, the alignment module 300 may be disposed to surround the tray 20 supplied to the stage 100, and may align the tray 20 by pressing at least a portion of the edge of the tray 20. A plurality of alignment modules 300 may be provided and disposed to be spaced apart from each other on the upper surface of the stage 100. The alignment module 300 may include an alignment member and an actuator.

The alignment member may be disposed parallel to at least a portion of the edge of the tray 20 seated on the upper surface of the stage 100. A plurality of alignment members may be provided and disposed to surround the edge of the tray 20. The plurality of alignment members may include a first alignment member 310, a second alignment member 320, a third alignment member 330, and a fourth alignment member 340.

The first alignment member 310 may be disposed on the upper surface of the stage 100 to be parallel to a first alignment surface 21 of the tray 20. A first pressing surface 311 that presses the first alignment surface 21 of the tray 20 and a second pressing surface 312 that presses a second alignment surface 22 of the tray 20 may be formed on the first alignment member 310.

The first pressing surface 311 may be formed to extend in one direction, which is the same direction as a direction in which the first alignment surface 21 extends. An extension length of the first pressing surface 311 may be formed to be smaller than an extension length of the first alignment surface 21. Since the extension length of the first pressing surface 311 is formed to be smaller than the extension length of the first alignment surface 21, the entirety of the first pressing surface 311 may be in contact with the first alignment surface 21 when the first pressing surface 311 presses the first alignment surface 21. A plurality of first pressing surfaces 311 may be provided and disposed to be spaced apart from each other. A spaced distance between the plurality of first pressing surfaces 311 may be smaller than the extension length of the first alignment surface 21.

The second pressing surface 312 may be formed to extend in the other direction, which is the same direction as a direction in which the second alignment surface 22 extends. An extension length of the second pressing surface 312 may be formed to be equal to or longer than an extension length of the second alignment surface 22. Since the extension length of the second pressing surface 312 is formed to be equal to or longer than the extension length of the second alignment surface 22, the entirety of the second alignment surface 22 may be in contact with the second pressing surface 312 when the second pressing surface 312 presses the second alignment surface 22. A plurality of second pressing surfaces 312 may be provided and extend in other directions from both sides of the first alignment surface 21.

The second alignment member 320 may be disposed on the upper surface of the stage 100 to be parallel to a side of the edge of the tray 20 positioned on the left side in FIG. 3. The second alignment member 320 may be in contact with the left side of the tray 20 to press the left side of the tray 20. The second alignment member 320 may be formed to have a length smaller than the left side of the tray 20.

The third alignment member 330 may be disposed on the upper surface of the stage 100 to be parallel to a side of the edge of the tray 20 positioned on the right side in FIG. 3. The third alignment member 330 may be in contact with the right side of the tray 20 to press the right side of the tray 20. The third alignment member 330 may be formed to have a length smaller than the left side of the tray 20.

The fourth alignment member 340 may be disposed on the upper surface of the stage 100 to be parallel to a side of the edge of the tray 20 opposite to the first alignment surface 21. The fourth alignment member 340 may be in contact with the side opposite to the first alignment surface 21 of the tray 20 to press the side opposite to the first alignment surface 21 of the tray 20. The fourth alignment member 340 may be formed to have a length smaller than the side opposite to the first alignment surface 21 of the tray 20.

The actuator may push the alignment member toward the tray 20. A plurality of actuators may be provided and disposed to be connected to each of the plurality of alignment members. The plurality of actuators may include a first actuator 350, a second actuator 360, a third actuator 370, and a fourth actuator 380.

The first actuator 350 may be disposed on the upper surface of the stage 100 to be connected to the first alignment member 310. The first actuator 350 may push the first alignment member 310 toward the tray 20 to allow the first pressing surface 311 of the first alignment member 310 to press the first alignment surface 21 of the tray 20 and allow the second pressing surface 312 of the first alignment member 310 to press the second alignment surface 22 of the tray 20. The first actuator 350 may be provided as a cylinder, linear motor, etc.

The second actuator 360 may be disposed on the upper surface of the stage 100 to be connected to the second alignment member 320. The second actuator 360 may push the second alignment member 320 toward the tray 20 to allow the second alignment member 320 to press the left side of the tray 20. The second actuator 360 may be provided as a cylinder, linear motor, etc.

The third actuator 370 may be disposed on the upper surface of the stage 100 to be connected to the third alignment member 330. The third actuator 370 may push the third alignment member 330 toward the tray 20 to allow the third alignment member 330 to press the right side of the tray 20. The third actuator 370 may be provided as a cylinder, linear motor, etc.

The fourth actuator 380 may be disposed on the upper surface of the stage 100 to be connected to the fourth alignment member 340. The fourth actuator 380 may push the fourth alignment member 340 toward the tray 20 to allow the fourth alignment member 340 to press the side of the tray 20 opposite to the first alignment surface 21. The fourth actuator 380 may be provided as a cylinder, linear motor, etc.

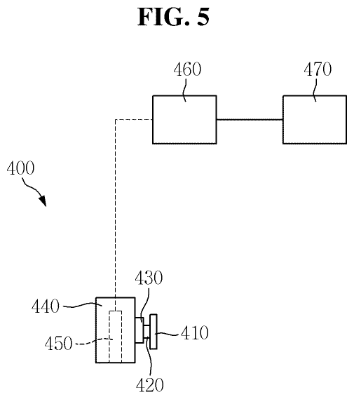

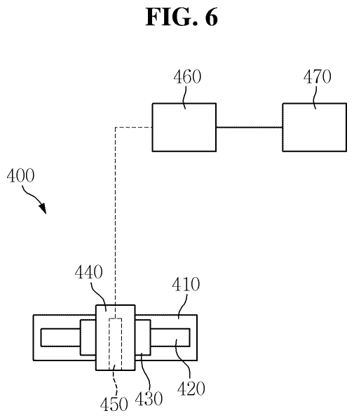

FIG. 5 is a front view illustrating an inspection module 400 of FIG. 1. FIG. 6 is a side view of FIG. 5.

Referring to FIGS. 1 to 6, the inspection module 400 may inspect an alignment state of the tray 20 aligned by the alignment module 300 on the upper surface of the stage 100. The inspection module 400 may be disposed on the adsorption portion 210 to be positioned above the tray 20. The inspection module 400 may include a base plate 410, a transfer rail 420, a transfer block 430, a camera holder 440, a camera 450, a display unit 460, and a control unit 470.

The base plate 410 may support one or more of the transfer rail 420, the transfer block 430, the camera holder 440, and the camera 450. The base plate 410 may be fixed to a side surface of the adsorption portion 210. The base plate 410 may be provided as a plate with a predetermined thickness and may be disposed so that one side thereof is fixed to the side surface of the adsorption portion 210.

The transfer rail 420 may provide a path along which the transfer block 430 is moved. The transfer rail 420 may be disposed on the other side surface opposite to one side surface of the base plate 410. The transfer rail 420 may extend in a direction horizontally perpendicular to the second direction. In other words, the transfer rail 420 may extend in the left and right directions of FIG. 2.

The transfer block 430 may be disposed on the transfer rail 420 and transferred along the transfer rail 420. A transfer driver (not illustrated) is disposed inside the transfer block 430, so that the transfer block 430 may be transferred along the transfer rail 420 according to the driving of the transfer driver. Since the transfer block 430 is transferred along the transfer rail 420, the transfer block 430 may be transferred in a direction horizontally perpendicular to the second direction.

The camera holder 440 may support the camera 450. An arrangement space in which the camera 450 is disposed may be formed inside the camera holder 440. The camera holder 440 may be formed to have an opened lower portion so that the camera 450 disposed in the arrangement space of the camera holder 440 may take a photograph from a lower side of the camera holder 440. The camera holder 440 may be disposed on the transfer block 430. As the camera holder 440 is disposed on the transfer block 430, the camera holder 440 may be transferred in a direction horizontally perpendicular to the second direction according to the transfer of the transfer block 430.

The camera 450 may be disposed in the arrangement space inside the camera holder 440. The camera 450 may photograph a contact area where the tray 20 and the alignment member come into contact. In particular, the camera 450 may photograph contact areas where the first alignment surface 21 and the second alignment surface 22 of the tray 20 are in contact with the first pressing surface 311 and the second pressing surface 312 of the first alignment member 310. The camera 450 may be provided as an endoscope camera.

The display unit 460 may display an image photographed by the camera 450. The display unit 460 may be connected to the camera 450 in a wired or wireless manner. When the camera 450 is provided as an endoscope camera, the display unit 460 may be a screen of the endoscope camera.

The control unit 470 may be connected to the display unit 460 and may analyze the image displayed on the display unit 460. The control unit 470 may determine the alignment state of the tray 20 aligned by the alignment module 300 on the upper surface of the stage 100 by analyzing the image displayed on the display unit 460. In other words, the control unit 470 may determine whether the aligned tray 20 is aligned at a correct position.

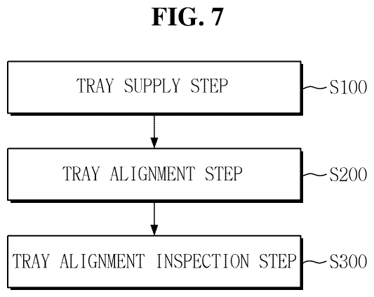

FIG. 7 is a flow chart illustrating a tray alignment inspection method according to an example embodiment of the present disclosure.

Referring to FIG. 7, a tray alignment inspection method according to an example embodiment of the present disclosure may include a tray supply step (S100), a tray alignment step (S200), and a tray alignment inspection step (S300).

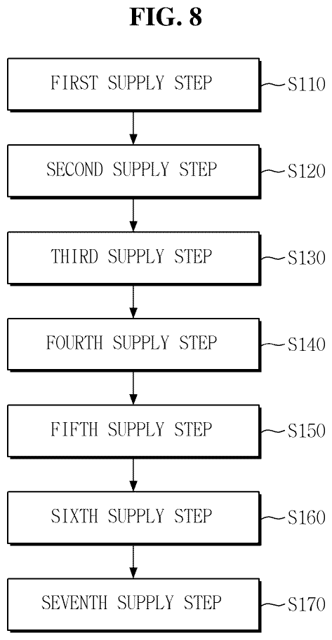

FIG. 8 is a flowchart illustrating the tray supply step (S100) of FIG. 7.

Referring to FIG. 8, the tray supply step (S100) may be a step in which the supply module 200 supplies the tray 20 to the stage 100. The tray supply step (S100) may include a first supply step (S110), a second supply step (S120), a third supply step (S130), a fourth supply step (S140), a fifth supply step (S150), a sixth supply step (S160), and a seventh supply step (S170).

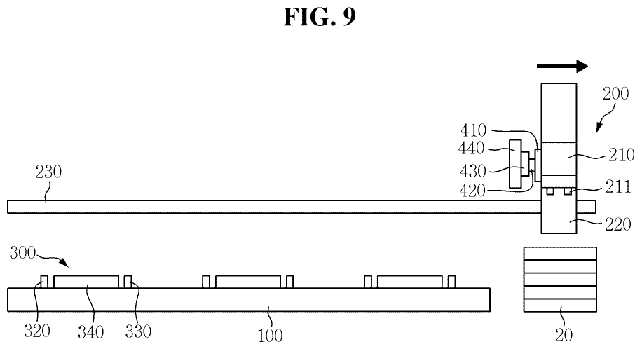

FIG. 9 is a view illustrating the first supply step (S110) of FIG. 8.

Referring to FIG. 9, the first supply step (S110) may be a step in which the adsorption portion 210 is moved in the second direction by the second moving portion 230 so that the adsorption nozzle 211 is positioned above the tray 20 stacked outside the stage 100. In the first supply step (S110), the first moving portion 220 is moved from the left to the right in FIG. 9 along the second moving portion 230, and the adsorption portion 210 connected to the first moving portion 220 is also moved from the left to the right in FIG. 9 as the first moving portion 220 is moved, such that the adsorption nozzle 211 of the adsorption portion 210 may be positioned above the tray 20.

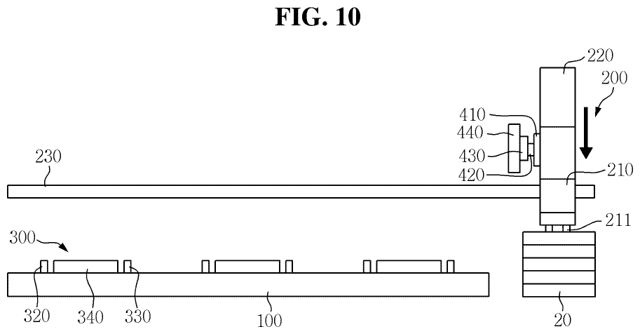

FIG. 10 is a view illustrating the second supply step (S120) of FIG. 8.

Referring to FIG. 10, the second supply step (S120) may be a step in which the adsorption portion 210 is moved in the first direction by the first moving portion 220 so that the adsorption nozzle 211 comes into contact with the tray 20. In the second supply step (S120), the adsorption portion 210 is moved from the upper side to the lower side in FIG. 10 by the first moving portion 220, so that the adsorption nozzle 211 may come into contact with an upper surface of a tray 20 stacked on the uppermost side among the stacked trays 20.

The third supply step (S130) may be a step in which the tray 20 is adsorbed to the adsorption nozzle 211. In the third supply step (S130), the tray 20 stacked on the uppermost side among the stacked trays 20 may be adsorbed and fixed to the adsorption nozzle 211 by the operation of the adsorption nozzle 211.

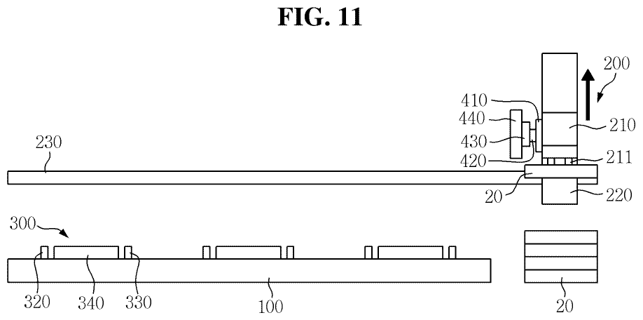

FIG. 11 is a view illustrating the fourth supply step (S140) of FIG. 8.

Referring to FIG. 11, the fourth supply step (S140) may be a step in which the adsorption portion 210 is moved in the first direction by the first moving portion 220. In the fourth supply step (S140), the adsorption portion 210 that adsorbs the tray 20 may be moved from the lower side to the upper side in FIG. 11 by the first moving portion 220.

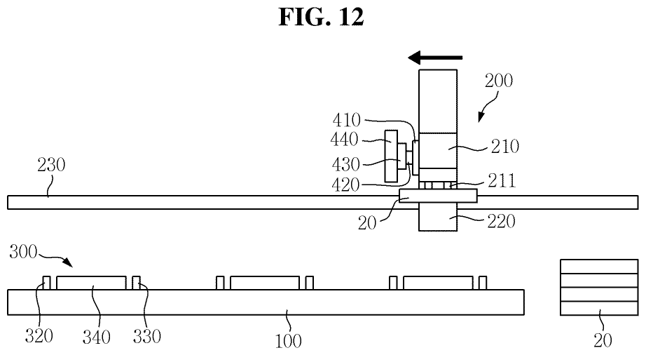

FIG. 12 is a view illustrating the fifth supply step (S150) of FIG. 8.

Referring to FIG. 12, the fifth supply step (S150) may be a step in which the adsorption portion 210 is moved in the second direction by the second moving portion 230 so that the adsorption portion 210 is positioned above the stage 100. In the fifth supply step (S150), the first moving portion 220 is moved from the right to the left in FIG. 12 along the second moving portion 230, and the adsorption portion 210 connected to the first moving portion 220 is also moved from the right to the left in FIG. 12 as the first moving portion 220 is moved, such that the adsorption portion 210 may be positioned above the stage 100. The fifth supply step (S150) may be a step in which the tray 20 adsorbed to the adsorption portion 210 is disposed above the alignment module 300.

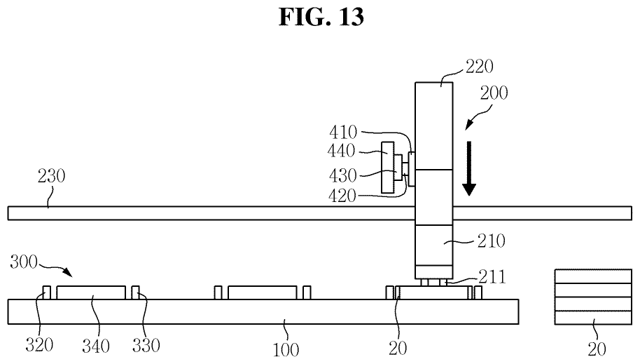

FIG. 13 is a view illustrating the sixth supply step (S160) of FIG. 8.

Referring to FIG. 13, the sixth supply step (S160) may be a step in which the adsorption portion 210 is moved in the first direction by the first moving portion 220 so that the tray 20 is seated on the upper surface of the stage 100. In the sixth supply step (S160), the adsorption portion 210 that adsorbs the tray 20 is moved from the upper side to the lower side in FIG. 13 by the first moving portion 220, so that the tray 20 may be seated on the upper surface of the stage 100. The sixth supply step (S160) may be a step in which the tray 20 is seated on the upper surface of the stage 100 so that the tray 20 is surrounded by the plurality of alignment members.

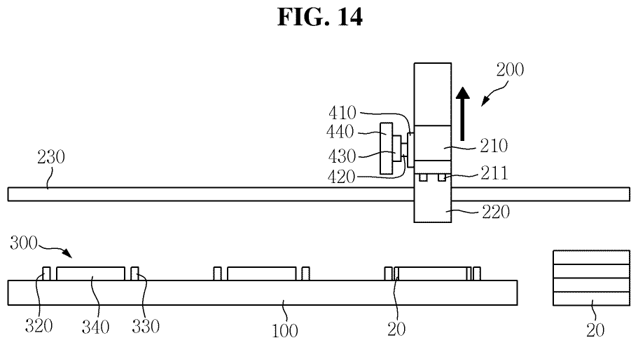

FIG. 14 is a view illustrating the seventh supply step (S170) of FIG. 8.

Referring to FIG. 14, the seventh supply step (S170) may be a step in which the operation of the adsorption nozzle 211 is stopped and the adsorption of the adsorption nozzle 211 and the tray 20 is released. In addition, the seventh supply step (S170) may be a step in which the adsorption portion 210 is moved in the first direction by the first moving portion 220. In the seventh supply step (S170), as the operation of the adsorption nozzle 211 is stopped, the adsorption nozzle 211 and the tray 20 may be separated, and the adsorption portion 210 may be moved from the lower side to the upper side in FIG. 14 by the first moving portion 220.

As the first supply step (S110), the second supply step (S120), the third supply step (S130), the fourth supply step (S140), the fifth supply step (S150), the sixth supply step (S160), and the seventh supply step (S170) described above are sequentially repeated, a plurality of trays 20 may be arranged on the upper surface of the stage 100 to be spaced apart from each other. Each tray 20 may be arranged on the upper surface of the stage 100 so as to be surrounded by a plurality of alignment members of each alignment module 300.

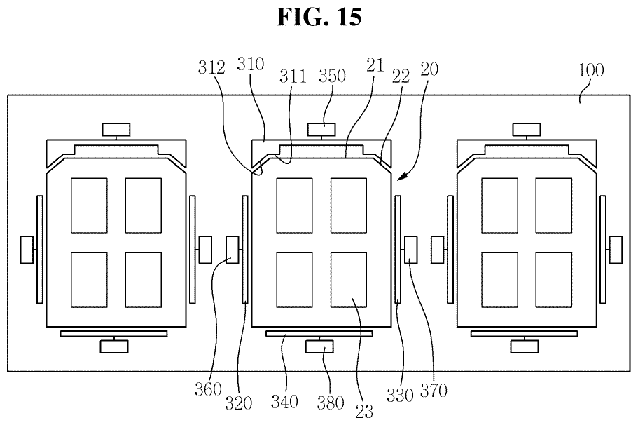

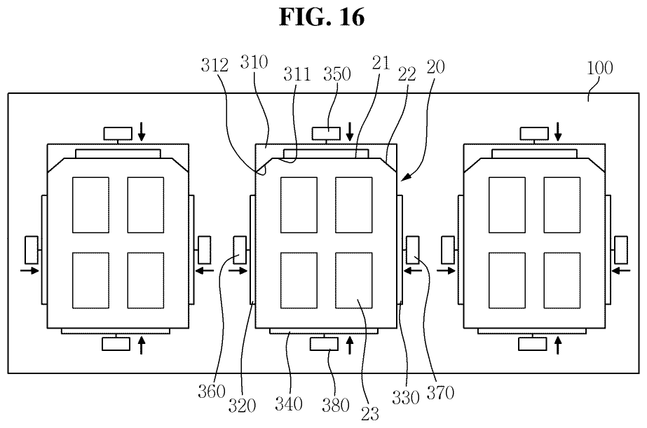

FIGS. 15 and 16 are views illustrating the tray alignment step (S200) of FIG. 7.

Referring to FIGS. 15 and 16, the tray alignment step (S200) may be a step in which the alignment module 300 aligns the trays 20 supplied to the stage 100. In other words, the tray alignment step (S200) may be a step of aligning the tray, as the actuator pushes the plurality of alignment members toward the tray 20 so that the plurality of alignment members of the alignment module 300 come into contact with the edge of the tray 20 and presses the edge of the tray 20.

In the tray alignment step (S200), as the first actuator 350 pushes the first alignment member 310 toward the tray 20, the first pressing surface 311 of the first alignment member 310 may be in contact with the first alignment surface 21 of the tray 20 and press the first alignment surface 21, and the second pressing surface 312 of the first alignment member 310 may be in contact with the second alignment surface 22 of the tray 20 and press the second alignment surface 22.

In addition, in the tray alignment step (S200), as the second actuator 360 pushes the second alignment member 320 toward the tray 20, the second alignment member 320 may press the left side of the tray 20.

In addition, in the tray alignment step (S200), as the third actuator 370 pushes the third alignment member 330 toward the tray 20, the third alignment member 330 may press the right side of the tray 20.

In addition, in the tray alignment step (S200), as the fourth actuator 380 pushes the fourth alignment member 340 toward the tray 20, the fourth alignment member 340 may press the side of the tray 20 opposite to the first alignment surface 21.

As described above, in the tray alignment step (S200), as a plurality of alignment members move the tray 20 by pressing the edge of the tray 20 from various directions, the tray 20 may be aligned in the correct position.

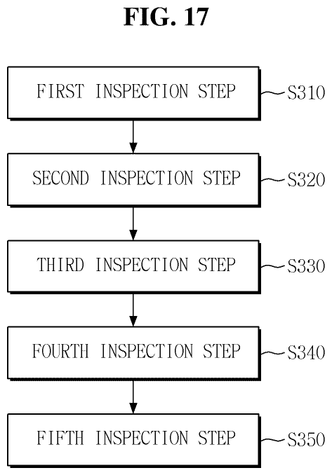

FIG. 17 is a flowchart illustrating the tray alignment inspection step (S300) of FIG. 7.

Referring to FIG. 17, the tray alignment inspection step (S300) may be a step of inspecting an alignment state of the tray 20 aligned on the stage 100. The tray alignment inspection step (S300) may include a first inspection step (S310), a second inspection step (S320), a third inspection step (S330), a fourth inspection step (S340), and a fifth inspection step (S350).

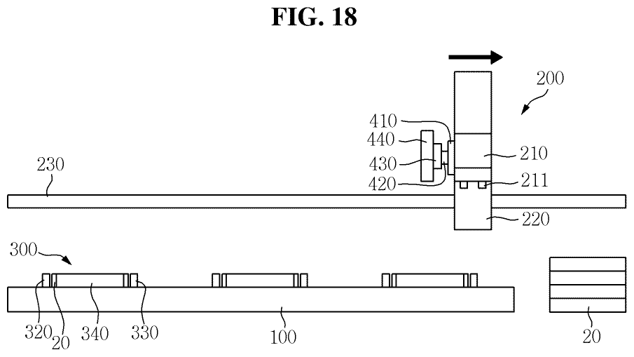

FIG. 18 is a view illustrating the first inspection step (S310) of FIG. 17.

Referring to FIG. 18, the first inspection step (S310) may be a step in which the adsorption portion 210 is moved in the second direction by the second moving portion 230 so that the camera holder 440 is positioned above the tray 20. In the first inspection step (S310), as the first moving portion 220 is moved from the left to the right in FIG. 18 along the second moving portion 230, the adsorption portion 210 may be moved so that the camera holder 440 is positioned above the tray 20.

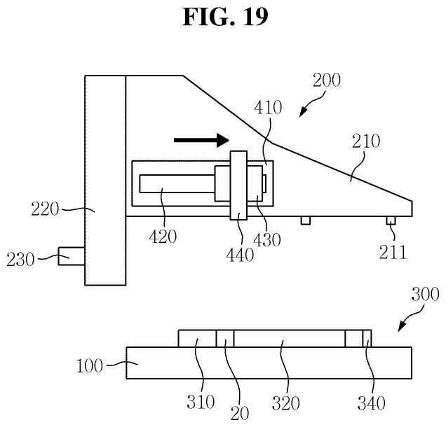

FIG. 19 is a view illustrating the second inspection step (S320) of FIG. 17.

Referring to FIG. 19, the second inspection step (S320) may be a step in which the transfer block 430 is transferred so that the camera 450 is positioned above at least one of a contact area where the first pressing surface 311 and the first alignment surface 21 are in contact and a contact area where the second pressing surface 312 and the second alignment surface 22 are in contact. In the second inspection step (S320), as the transfer block 430 is moved from the left to the right in FIG. 19, the camera 450 may be positioned above at least one contact area. In the second inspection step (S320), the camera 450 may be positioned above at least one contact area, but may also be positioned at a position where all contact areas may be photographed.

The third inspection step (S330) may be a step in which the camera 450 photographs at least one of a contact area where the first pressing surface 311 and the first alignment surface 21 are in contact and a contact area where the second pressing surface 312 and the second alignment surface 22 are in contact. In the third inspection step (S330), the camera 450 may photograph at least one contact area, but may also photograph all contact areas at once.

The fourth inspection step (S340) may be a step in which the display unit 460 displays an image photographed by the camera 450.

The fifth inspection step (S350) may be a step in which the control unit 470 determines an alignment state of the tray 20 by analyzing the image displayed on the display unit 460.

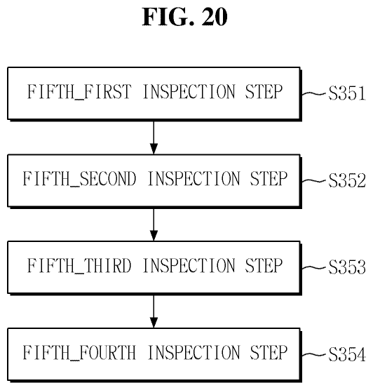

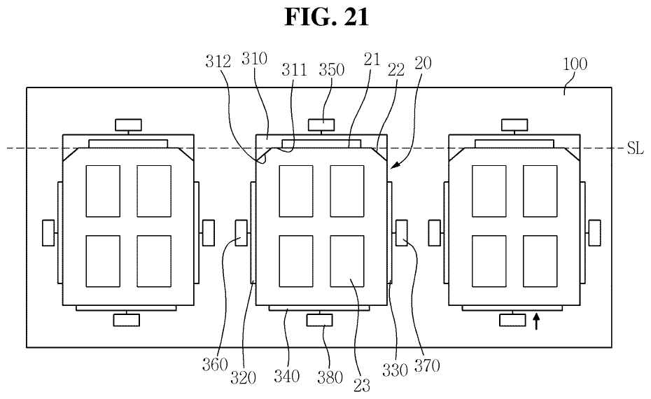

FIG. 20 is a flowchart illustrating the fifth inspection step (S350) of FIG. 17. FIG. 21 is a view illustrating the fifth inspection step (S350) of FIG. 20.

Referring to FIGS. 20 and 21, the fifth inspection step (S350) may include a fifth_first inspection step (S351), a fifth_second inspection step (S352), a fifth_third inspection step (S353), and a fifth_fourth inspection step (S354).

The fifth_first inspection step (S351) may be a step in which the control unit 470 sets a virtual reference line SL above the stage 100. The virtual reference line SL may be a line along which the first alignment surface 21 of the tray 20 needs to be positioned when the tray 20 is aligned in the correct position. Since the position where the reference line SL is set may vary depending on a size of the tray 20, the control unit 470 may determine the size of the tray 20 and set the reference line SL suitable for the size of the tray 20.

The fifth_second inspection step (S352) may be a step in which the control unit 470 determines whether the entirety of the first alignment surface 21 of the tray 20 is positioned on the reference line SL. For example, when the entirety of the first alignment surface 21 does not match the reference line SL, the control unit 470 may determine that the tray 20 is not correctly aligned.

The fifth_third inspection step (S353) may be a step in which the control unit 470 determines whether the second pressing surface 312 of the first alignment member 310 and the entirety of the second alignment surface 22 of the tray 20 are in contact. For example, when the entirety of the second alignment surface 22 is not in contact with the second pressing surface 312, the control unit 470 may determine that the tray 20 is not correctly aligned.

The fifth_fourth inspection step (S354) may be a step in which the control unit 470 determines the alignment state of the tray 20 according to the determination results of the fifth_second inspection step (S352) and the fifth_third inspection step (S353). When it is determined in the fifth_second inspection step (S352) that entirety of the first alignment surface 21 of the tray 20 is positioned on the reference line SL, and it is determined in the fifth_third inspection step (S353) that the second pressing surface 312 of the first alignment member 310 and the entirety of the second alignment surface 22 of the tray 20 are in contact, the control unit 470 may determine that the tray 20 is aligned in the correct position.

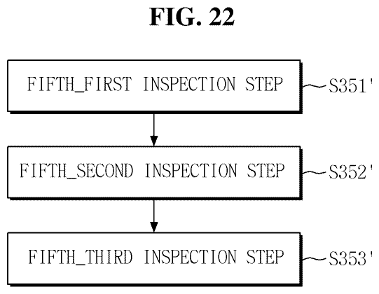

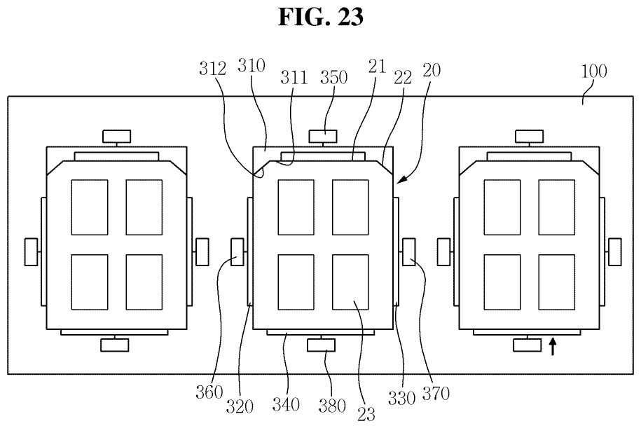

FIG. 22 is a flowchart illustrating the fifth inspection step (S350) of FIG. 17. FIG. 23 is a view illustrating the fifth inspection step (S350) of FIG. 22.

Referring to FIGS. 22 and 23, the fifth inspection step (S350) may include a fifth_first inspection step (S351′), a fifth_second inspection step (S352′), and a fifth_third inspection step (S353′).

The fifth_first inspection step (S351′) may be a step in which the control unit 470 determines whether the entirety of the first pressing surface 311 of the first alignment member 310 and the first alignment surface 21 of the tray 20 are in contact. For example, when the entirety of the first pressing surface 311 is not in contact with the first alignment surface 21, the control unit 470 may determine that the tray 20 is not correctly aligned.

The fifth_second inspection step (S352′) may be a step in which the control unit 470 determines whether the second pressing surface 312 of the first alignment member 310 and the entirety of the second alignment surface 22 of the tray 20 are in contact. For example, when the entirety of the second alignment surface 22 is not in contact with the second pressing surface 312, the control unit 470 may determine that the tray 20 is not correctly aligned.

The fifth_third inspection step (S353′) may be a step in which the control unit 470 determines the alignment state of the tray 20 according to the determination results of the fifth_first inspection step (S351′) and the fifth_second inspection step (S352′). When it is determined in the fifth_first inspection step (S351′) that the entirety of the first pressing surface 311 of the first alignment member 310 and the first alignment surface 21 of the tray 20 are in contact, and it is determined in the fifth_second inspection step (S352′) that the second pressing surface 312 of the first alignment member 310 and the entirety of the second alignment surface 22 of the tray 20 are in contact, the control unit 470 may determine that the tray 20 is aligned in the correct position.

In the present example embodiment, it is described that the control unit 470 determines the alignment state of the tray 20, but the present disclosure is not limited thereto. The control unit 470 may determine the alignment state of the tray 20, but the operator may also determine the alignment state of the tray 20 by reading the image displayed on the display unit 460.

When the control unit 470 or the operator determines that the tray 20 is not correctly aligned, the alignment of the tray 20 may be attempted again by restarting the alignment module 300.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A tray alignment device comprising:
a stage;
a supply module that supplies a tray to the stage;
an alignment module disposed to surround the tray supplied to the stage and aligning the tray by pressing at least a portion of an edge of the tray; and
an inspection module that inspects an alignment of the tray.

2. The tray alignment device of claim 1, wherein the supply module includes:
an adsorption portion disposed above the stage and including an adsorption nozzle for adsorbing the tray;
a first moving portion that moves the adsorption portion in a first direction; and
a second moving portion that moves the adsorption portion in a second direction.

3. The tray alignment device of claim 2, wherein the first direction is a direction perpendicular to an upper surface of the stage, and
the second direction is a direction parallel to the upper surface of the stage.

4. The tray alignment device of claim 2, wherein a plurality of trays are provided and arranged to be spaced apart from each other on the upper surface of the stage, and
the second direction is a direction parallel to a direction in which the trays are arranged.

5. The tray alignment device of claim 2, wherein the inspection module is disposed on the adsorption portion to be positioned above the tray.

6. The tray alignment device of claim 2, wherein the alignment module includes:
an alignment member disposed adjacent to at least the portion of the edge of the tray; and
an actuator that pushes the alignment member toward the tray so that the alignment member contacts and presses at least the portion of the edge of the tray.

7. The tray alignment device of claim 6, wherein the tray includes a first alignment surface extending in one direction and a second alignment surface extending in an oblique direction relative to the one direction, and
the alignment member includes a first pressing surface extending in the one direction to press the first alignment surface and a second pressing surface extending in the oblique direction to press the second alignment surface.

8. The tray alignment device of claim 7, wherein an extension length of the first pressing surface of the alignment member is smaller than an extension length of the first alignment surface of the tray, so that an entirety of the first pressing surface is in contact with the first alignment surface, and
an extension length of the second pressing surface of the alignment member is equal to or longer than an extension length of the second alignment surface of the tray, so that the second pressing surface is in contact with an entirety of the second alignment surface.

9. The tray alignment device of claim 6, wherein the inspection module includes:
a transfer rail disposed on the adsorption portion;
a transfer block disposed on the transfer rail and transferred along the transfer rail;
a camera holder disposed on the transfer block; and
a camera disposed in or on the camera holder to photograph a contact area where the tray and the alignment member come into contact.

10. The tray alignment device of claim 9, wherein the transfer rail extends in a direction horizontally perpendicular to the second direction.

11. The tray alignment device of claim 9, wherein the inspection module further includes:
a display unit that displays an image photographed by the camera; and
a control unit that determines the alignment state of the tray by analyzing the image displayed on the display unit.

12. A tray alignment inspection method comprising:
a tray supply step of supplying a tray to a stage;
a tray alignment step of aligning the tray supplied to the stage; and
a tray alignment inspection step of inspecting an alignment state of the tray aligned on the stage.

13. The tray alignment inspection method of claim 12, wherein the tray supply step includes:
a first supply step in which an adsorption portion moves in a second direction so that the adsorption portion for adsorbing the tray is positioned above the tray positioned outside the stage;
a second supply step in which the adsorption portion moves in a first direction so as to be in contact with the tray;
a third supply step in which the tray is adsorbed to the adsorption portion;
a fourth supply step in which the adsorption portion that adsorbs the tray moves in the first direction;
a fifth supply step in which the adsorption portion moves in the second direction so as to be positioned above the stage;
a sixth supply step in which the adsorption portion moves in the first direction so that the tray is seated on an upper surface of the stage; and
a seventh supply step in which the adsorption of the adsorption portion and the tray is released.

14. The tray alignment inspection method of claim 13, wherein the first direction is a direction perpendicular to the upper surface of the stage, and
the second direction is a direction parallel to the upper surface of the stage.

15. The tray alignment inspection method of claim 13, wherein in the sixth supply step, the tray is seated on the upper surface of the stage so that at least a portion of an edge of the tray is disposed adjacent to an alignment member disposed on the upper surface of the stage.

16. The tray alignment inspection method of claim 15, wherein in the tray alignment step, the alignment member contacts and presses at least the portion of the edge of the tray.

17. The tray alignment inspection method of claim 16, wherein in the tray alignment step,
a first pressing surface of the alignment member contacts a first alignment surface of the tray and presses the first alignment surface, and
a second pressing surface of the alignment member contacts a second alignment surface of the tray and presses the second alignment surface.

18. The tray alignment inspection method of claim 17, wherein the tray alignment inspection step includes:
a first inspection step in which the adsorption portion moves in the second direction so that a camera disposed on the adsorption portion is positioned above the tray;
a second inspection step in which the camera moves to be positioned above at least one of a contact area where the first pressing surface contacts the first alignment surface and a contact area where the second pressing surface contacts the second alignment surface; and
a third inspection step in which the camera photographs at least one of the contact areas.

19. The tray alignment inspection method of claim 18, wherein the tray alignment inspection step further includes:
a fourth inspection step in which an image photographed by the camera is displayed on a display unit; and
a fifth inspection step of determining the alignment state of the tray by analyzing the image displayed on the display unit.

20. The tray alignment inspection method of claim 19, wherein the fifth inspection step includes:
a fifth_first inspection step of setting a virtual reference line above the stage;
a fifth_second inspection step of determining whether an entirety of the first alignment surface is positioned on the reference line;
a fifth_third inspection step of determining whether the second pressing surface and an entirety of the second alignment surface are in contact with each other; and
a fifth_fourth inspection step of determining the alignment state of the tray according to the determination results of the fifth_second inspection step and the fifth_third inspection step.

21. The tray alignment inspection method of claim 20, wherein in the fifth_fourth inspection step, when it is determined in the fifth_second inspection step that the entirety of the first alignment surface is positioned on the reference line and it is determined in the fifth_third inspection step that the second pressing surface and the entirety of the second alignment surface are in contact with each other, it is determined that the tray is positioned in a correct position.

22. The tray alignment inspection method of claim 19, wherein the fifth inspection step includes:
a fifth_first inspection step of determining whether an entirety of the first pressing surface and the first alignment surface are in contact with each other;
a fifth_second inspection step of determining whether the second pressing surface and an entirety of the second alignment surface are in contact with each other; and
a fifth_third inspection step of determining the alignment state of the tray according to the determination results of the fifth_first inspection step and the fifth_second inspection step.

23. The tray alignment inspection method of claim 22, wherein in the fifth_third inspection step, when it is determined in the fifth_first inspection step that the entirety of the first pressing surface and the first alignment surface are in contact with each other and it is determined in the fifth_second inspection step that the second pressing surface and the entirety of the second alignment surface are in contact with each other, it is determined that the tray is positioned in a correct position.
